(19) United States
(12) Patent Application Publication
(10) Pub. No.: US 2017/0256407 A1
(43) Pub. Date: Sep. 7, 2017

(54) METHOD FOR PRODUCING NITRIDE SEMICONDUCTOR STACKED BODY AND NITRIDE SEMICONDUCTOR STACKED BODY

(71) Applicant: SHARP KABUSHIKI KAISHA, Sakai City, Osaka (JP)

(72) Inventors: Masayuki TAJIRI, Sakai City, Osaka (JP); Nobuyuki ITO, Sakai City, Osaka (JP); Atsushi OGAWA, Sakai City, Osaka (JP); Yohsuke FUJISHIGE, Sakai City, Osaka (JP); Mai OKAZAKI, Sakai City, Osaka (JP); Manabu TOHSAKI, Sakai City, Osaka (JP)

(73) Assignee: SHARP KABUSHIKI KAISHA, Sakai City, Osaka (JP)

(21) Appl. No.: 15/507,663

(22) PCT Filed: Aug. 28, 2015
(86) PCT No.: PCT/JP2015/074363

§ 371 Date: Feb. 28, 2017

(30) Foreign Application Priority Data
Sep. 9, 2014 (JP) 2014-183463

(51) Int. Cl. H01L 21/02; H01L 29/66; H01L 29/205; H01L 29/778; H01L 29/20

(52) U.S. Cl. CPC H01L 21/02694; H01L 29/7787; H01L 29/2003; H01L 29/205; H01L 29/66462; H01L 21/02458; H01L 21/0254

(57) ABSTRACT

A method for producing a nitride semiconductor stacked body includes: a first nitride semiconductor layer forming step of forming a first nitride semiconductor layer above a substrate within a reaction furnace; a second nitride semiconductor layer forming step of forming a second nitride semiconductor layer above the first nitride semiconductor layer; and a third nitride semiconductor layer forming step of forming a third nitride semiconductor layer on the upper surface of the second nitride semiconductor layer, the third nitride semiconductor layer having a band gap larger than the band gap of the second nitride semiconductor layer. No interval is provided between the second nitride semiconductor layer forming step and the third nitride semiconductor layer forming step, and the third nitride semiconductor layer forming step is performed continuously after the second nitride semiconductor layer forming step.

### TECHNICAL FIELD

The present invention relates to a method for producing a nitride semiconductor stacked body typified by a semiconductor switching element such as an HEMT (High Electron Mobility Transistor) and to a nitride semiconductor stacked body.

### BACKGROUND ART

Nitride semiconductors are group III-V compound semiconductors typified by GaN (gallium nitride). In recent years, their application to switching elements used for power devices etc. is expected. This is because of the following reason. The band gap of the nitride semiconductors is about 3.4 eV, which is larger than the band gap of conventional semiconductors using Si (silicon). The dielectric breakdown electric field of the nitride semiconductors is about 10 times higher, and their electron saturation velocity is about 2.5 times higher than those of the conventional semiconductors. Therefore, the nitride semiconductors have characteristics suitable for power devices. For example, in one proposed switching element, a GaN/AlGaN heterostructure is disposed on a substrate made of SiC (silicon carbide), Al₂O₃ (sapphire), Si, etc. (see, for example, U.S. Pat. No. 6,849,882 (PTL 1)). The AlGaN is a mixture of GaN and AlN (aluminum nitride).

In the above switching element, polarization due to the piezoelectric effect caused by the lattice mismatch between the AlGaN and GaN, together with spontaneous polarization due to the asymmetric wurtzite crystal structure of the GaN in its C-axis direction, causes the formation of a two-dimensional electron gas with a high electron density of about 1×10¹² cm⁻² to about 1×10¹³ cm⁻². In this switching element, the electron density in the two-dimensional electron gas is controlled to switch between a state in which prescribed electrodes are electrically connected to each other (an ON state) and a state in which the prescribed electrodes are not electrically connected to each other (an OFF state).

An example of a typical structure of the above-described switching element will next be described with reference to FIGS. 7 and 8. FIGS. 7 and 8 are schematic cross-sectional views showing a typical structure of a conventional switching element 1000. FIG. 7 shows the switching element 1000 in an ON state. FIG. 8 shows the switching element 1000 in an OFF state.

As shown in FIGS. 7 and 8, the switching element 1000 includes a substrate 1001, a buffer layer 1002 formed on the upper surface of the substrate 1001, an electron transit layer 1003 made of undoped GaN and formed on the upper surface of the buffer layer 1002, an electron supply layer 1004 made of AlGaN and formed on the upper surface of the electron transit layer 1003, a source electrode 1005, a drain electrode 1006, and a gate electrode 1007. The source electrode 1005, the drain electrode 1006, and the gate electrode 1007 are formed on the upper surface of the electron supply layer 1004. The gate electrode 1007 is positioned between the source electrode 1005 and the drain electrode 1006.

The switching element 1000 is of the normally-on type. Therefore, as shown in FIG. 7, when the potential of the gate electrode 1007 is the same as the potential of the source electrode 1005 or when the gate electrode 1007 is open, a two-dimensional electron gas layer 1008 is formed in the vicinity of the joint interface between the electron transit layer 1003 and the electron supply layer 1004, and the switching element 1000 is in an ON state. In the switching element 1000 in the ON state, electric current flows between the source electrode 1005 and the drain electrode 1006 when the potential of the drain electrode 1006 is higher than the potential of the source electrode 1005.

Meanwhile, as shown in FIG. 8, when the potential of the gate electrode 1007 is lower than a threshold voltage with respect to the potential of the source electrode 1005, the two-dimensional electron gas layer 1008 is not formed in a region below the gate electrode 1007 and in the vicinity of the joint interface between the electron transit layer 1003 and the electron supply layer 1004. Specifically, a depletion region 1009 is formed below the gate electrode 1007. In this case, the switching element 1000 is in an OFF state, and no current flows between the source electrode 1005 and the drain electrode 1006.

To reduce the ON resistance by increasing the density and mobility of electrons in the two-dimensional electron gas layer 1008, it is contemplated to use a method in which an electron supply layer made of AlGaN and AlN is used instead of the electron supply layer 1004 made of AlGaN.

An example of a switching element including the electron supply layer made of AlGaN and AlN will be described with reference to FIG. 9. FIG. 9 is a schematic cross-sectional view for illustrating the switching element 2000 including the electron supply layer 2004 made of AlGaN and AlN. In the switching element 2000 shown in FIG. 9, the same parts as those in the switching element 1000 shown in FIGS. 7 and 8 are denoted by the same numerals, and their repeated description will be omitted.

As shown in FIG. 9, the switching element 2000 includes a substrate 1001, a buffer layer 1002, an electron transit layer 1003, an electron supply layer 2004, a source electrode 1005, a drain electrode 1006, and a gate electrode 1007. The electron supply layer 2004 includes a spacer layer 2004A made of AlN and a barrier layer 2004B made of AlGaN.

The difference between the band gap of the spacer layer 2004A and the band gap of the electron transit layer 1003 is larger than the difference between the band gap of the spacer layer 2004A and the band gap of the barrier layer 20046. In addition, the lattice mismatch between the spacer layer 2004A and the electron transit layer 1003 is larger than the lattice mismatch between the spacer layer 2004A and the barrier layer 20046. Therefore, the density and mobility of electrons in the two-dimensional electron gas layer 1008 become high, and the ON resistance becomes low.

### CITATION LIST

### Patent Literature

PTL 1: U.S. Pat. No. 6,849,882

### SUMMARY OF INVENTION

### Technical Problem

However, in the above switching element 2000, during the formation of the spacer layer 2004A, the electron transit layer 1003 serving as the base layer for the spacer layer 2004A is decomposed, and irregularities are formed on the upper surface of the electron transit layer 1003 (the interface between the electron transit layer 1003 and the spacer layer 2004A). The spacer layer 2004A formed on the upper surface of the electron transit layer 1003 is very thin, i.e., 5 nm or less. Therefore, the spacer layer 2004A is influenced by the irregularities on the upper surface of the electron transit layer 1003, and the thickness of the spacer layer 2004A becomes nonuniform. When the states of the electron transit layer 1003 and the spacer layer 2004A in in-plane directions are nonuniform, the characteristics of the switching element 2000 deteriorate, e.g., the mobility of electrons is reduced.

As described above, the irregularities on the upper surface of the electron transit layer 1003 are problematic because they cause deterioration of the characteristics of the switching element 2000.

Referring next to FIG. 10, a description will be given of the phenomenon in which irregularities are formed on the upper surface of the electron transit layer 1003. FIG. 10 is a schematic cross-sectional view for illustrating the phenomenon in which irregularities are formed on the upper surface of the electron transit layer 1003 of the switching element 2000. In FIG. 10, an MOCVD (Metal Organic Chemical Vapor Deposition) method that is the most widely used mass production method for semiconductor elements is used as a method for forming the spacer layer 2004A made of AlN. In FIG. 10, a carrier gas that carries an organometallic material in liquid form to a reaction furnace is H₂ (hydrogen) that is most widely used in terms of preventing oxidation of raw materials and the product.

As shown in FIG. 10, in the course of the formation of the spacer layer 2004A made of AlN on the upper surface of the electron transit layer 1003 made of GaN, the CaN forming the electron transit layer 1003 is decomposed into Ga (gallium) and N (nitrogen). This is because the substrate temperature required to grow AlN forming the spacer layer 2004A (900° C. or higher) is higher than the substrate temperature at which the GaN forming the electron transit layer 1003 undergoes thermal decomposition (800° C. or higher). N generated by the thermal decomposition of the GaN leaves as gaseous N₂ (nitrogen) or reacts with H₂ in the surrounding gas and leaves as NH₃ (ammonia).

As described above, when the amount of H₂, i.e., the carrier gas, around the GaN is abundant at the time N leaves the electron transit layer 1003, H (hydrogen) and the N generated by thermal decomposition can easily react with each other. This facilitates consumption of N and thereby facilitates thermal decomposition.

In terms of preventing the reaction of the raw materials in the vapor phase to facilitate the reaction of the raw materials on the substrate 1001, it is preferable that the AlN is grown with the pressure in the reaction furnace reduced (for example, to 0.1 atm or lower). However, when the pressure in the reaction furnace is reduced, N₂ and NH₃ leave in an accelerated manner, and the thermal decomposition is facilitated.

When the thermal decomposition is facilitated, irregularities are formed on the upper surface of the electron transit layer 1003.

Accordingly, it is an object of the invention to provide a nitride semiconductor stacked body production method in which the formation of irregularities on the upper surface of a specific nitride semiconductor layer can be prevented and to provide a nitride semiconductor stacked body.

One example of the nitride semiconductor stacked body is a nitride semiconductor stacked substrate including a substrate and a plurality of nitride semiconductor layers stacked on the substrate.

Another example of the nitride semiconductor stacked body is a nitride semiconductor stacked device (for example, a switching element) formed using the above nitride semiconductor stacked substrate.

The switching element 2000 in FIG. 9 is presented for the sake of convenience in order to clarify the object of the invention and is not a known technology.

### Solution to Problem

To achieve the above object, the nitride semiconductor stacked body production method of the invention comprises:

a first nitride semiconductor layer forming step of forming a first nitride semiconductor layer above a substrate within a reaction furnace;

a second nitride semiconductor layer forming step of forming a second nitride semiconductor layer above the first nitride semiconductor layer; and

a third nitride semiconductor layer forming step of forming a third nitride semiconductor layer on an upper surface of the second nitride semiconductor layer, the third nitride semiconductor layer having a band gap larger than a band gap of the second nitride semiconductor layer,

wherein no interval is provided between the second nitride semiconductor layer forming step and the third nitride semiconductor layer forming step, and the third nitride semiconductor layer forming step is performed continuously after the second nitride semiconductor layer forming step.

In one embodiment of the nitride semiconductor stacked body production method,

the second nitride semiconductor layer forming step includes:

a fourth nitride semiconductor layer forming step of forming a fourth nitride semiconductor layer; and

a fifth nitride semiconductor layer forming step of forming a fifth nitride semiconductor layer above the fourth nitride semiconductor layer,

wherein a temperature of the substrate in the fifth nitride semiconductor layer forming step is higher than the temperature of the substrate in the fourth nitride semiconductor layer forming step, and

wherein a pressure inside the furnace in the fifth nitride semiconductor layer forming step is lower than the pressure inside the furnace in the fourth nitride semiconductor layer forming step

In another embodiment of the nitride semiconductor stacked body production method,

the second nitride semiconductor layer forming step further includes a sixth nitride semiconductor layer forming step of forming a sixth nitride semiconductor layer between the fourth nitride semiconductor layer and the fifth nitride semiconductor layer,

wherein the temperature of the substrate in the sixth nitride semiconductor layer forming step gradually changes from the temperature of the substrate in the fourth nitride semiconductor layer forming step to the temperature of the substrate in the fifth nitride semiconductor layer forming step, and

wherein the pressure inside the furnace in the sixth nitride semiconductor layer forming step gradually changes from the pressure inside the furnace in the fourth nitride semiconductor layer forming step to the pressure inside the furnace in the fifth nitride semiconductor layer forming step.

In another embodiment of the nitride semiconductor stacked body production method,

the second nitride semiconductor layer is made of GaN, and

the third nitride semiconductor layer is made of AlₓGa₁₋ₓN (0<x<1).

The nitride semiconductor stacked body of the invention comprises:

a substrate;

a first nitride semiconductor layer formed above the substrate;

a second nitride semiconductor layer formed above the first nitride semiconductor layer; and

a third nitride semiconductor layer formed on an upper surface of the second nitride semiconductor layer and having a band gap larger than a band gap of the second nitride semiconductor layer,

wherein the second nitride semiconductor layer and the third nitride semiconductor layer are formed such that no interval is provided between formation of the second nitride semiconductor layer and formation of the third nitride semiconductor layer and that the formation of the third nitride semiconductor layer is performed continuously after the formation of the second nitride semiconductor layer.

In one embodiment of the nitride semiconductor stacked body,

the second nitride semiconductor layer includes:

a fourth nitride semiconductor layer having a carbon concentration of less than 5×10¹⁶/cm³; and

a fifth nitride semiconductor layer formed above the fourth nitride semiconductor layer and having a carbon concentration of 5×10¹⁶/cm³ or more and less than 1×10¹⁸/cm³.

In another embodiment of the nitride semiconductor stacked body,

the second nitride semiconductor layer further includes a sixth nitride semiconductor layer formed between the fourth nitride semiconductor layer and the fifth nitride semiconductor layer,

wherein the sixth nitride semiconductor layer has a carbon concentration that gradually increases from a lower portion of the sixth nitride semiconductor layer to an upper portion of the sixth nitride semiconductor layer, the carbon concentration of the sixth nitride semiconductor layer in the vicinity of an interface between the fourth nitride semiconductor layer and the sixth nitride semiconductor layer being substantially the same as the carbon concentration of the fourth nitride semiconductor layer, the carbon concentration of the sixth nitride semiconductor layer in the vicinity of an interface between the fifth nitride semiconductor layer and the sixth nitride semiconductor layer being substantially the same as the carbon concentration of the fifth nitride semiconductor layer.

In another embodiment of the nitride semiconductor stacked body,

the second nitride semiconductor layer is made of GaN, and the third nitride semiconductor layer is made of AlₓGa₁₋ₓN (0<x<1).

In another embodiment of the nitride semiconductor stacked body,

an upper surface of the third nitride semiconductor layer has a surface roughness of 0.5 nm or less as measured by an atomic force microscope in a 1 μm×1 μm scanning area.

### Advantageous Effects of Invention

In the nitride semiconductor stacked body production method of the invention, no interval is provided between the second nitride semiconductor layer forming step and the third nitride semiconductor layer forming step, and the third nitride semiconductor layer forming step is performed continuously after the second nitride semiconductor layer forming step. This can prevent the formation of irregularities on the upper surface of the second nitride semiconductor. Therefore, the formation of irregularities on the upper surface of a specific nitride semiconductor layer can be prevented.

In the nitride semiconductor stacked body of the invention, the second nitride semiconductor layer and the third nitride semiconductor layer are formed such that no interval is provided between the formation of the second nitride semiconductor layer and the formation of the third nitride semiconductor layer and that the formation of the third nitride semiconductor layer is performed continuously after the formation of the second nitride semiconductor layer. This can prevent the formation of irregularities on the upper surface of the second nitride semiconductor. Therefore, the formation of irregularities on the upper surface of a specific nitride semiconductor layer can be prevented.

### BRIEF DESCRIPTION OF DRAWINGS

FIG. 1 is a schematic cross-sectional view of a switching element in a first embodiment of the invention.

FIG. 2 is a sequence diagram for illustrating an electron transit layer forming step and an electron supply layer forming step in the first embodiment of the invention.

FIG. 3 is a schematic cross-sectional view of a switching element in a second embodiment of the invention.

FIG. 4 is a sequence diagram for illustrating an electron transit layer forming step and an electron supply layer forming step in the second embodiment of the invention.

FIG. 5 is a schematic cross-sectional view of a switching element in a third embodiment of the invention.

FIG. 6 is a sequence diagram for illustrating an electron transit layer forming step and an electron supply layer forming step in the third embodiment of the invention.

FIG. 7 is a schematic cross-sectional view of a conventional switching element in an ON state.

FIG. 8 is a schematic cross-sectional view of the conventional switching element in an OFF state.

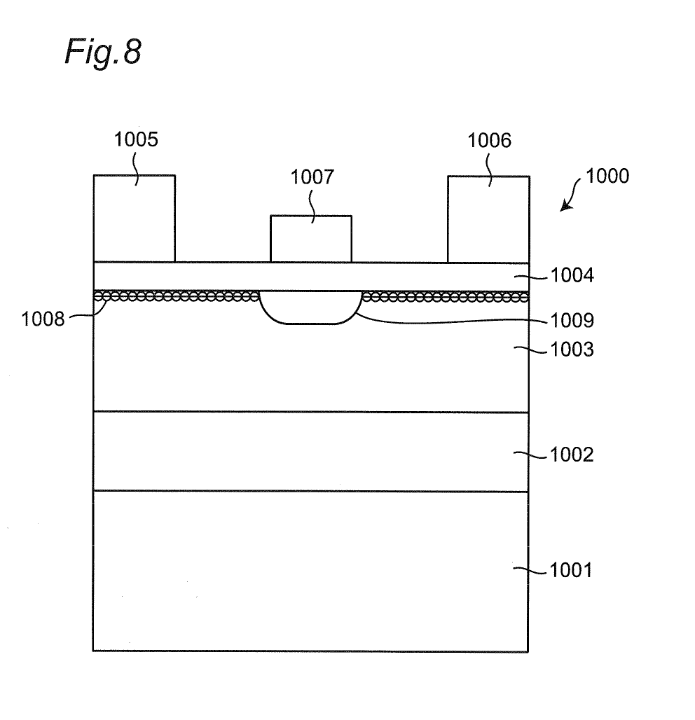

FIG. 9 is a schematic cross-sectional view of a switching element in a reference example.

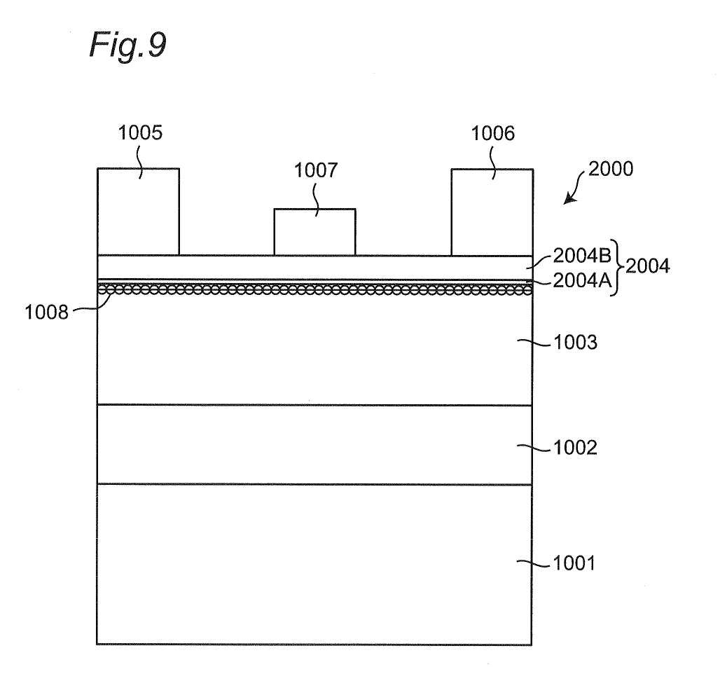

FIG. 10 is a schematic cross-sectional view for illustrating a phenomenon in which irregularities are formed on the upper surface of an electron transit layer in the reference example.

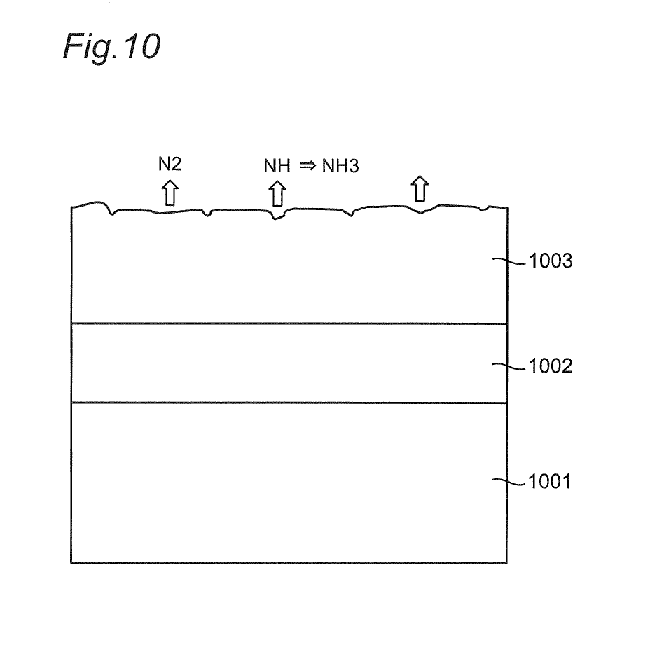

### DESCRIPTION OF EMBODIMENTS

Nitride semiconductor stacked bodies (particularly nitride semiconductor stacked substrates) according to embodiments of the invention and production methods therefor will be described with reference to the drawings. To make the description concrete, switching elements, which are nitride semiconductor stacked devices using the nitride semiconductor stacked substrates according to the embodiments of the invention, will be described as examples. In the cross-sectional views referred to in the following description, principal parts are emphasized for the sake of convenience of the description, and the dimensional ratios of components in the drawings do not necessarily coincide with the actual dimensional ratios. In the drawings referred to in the following description, the same components are denoted by the same symbols for the sake of convenience of the description.

In the following description, elements (materials) forming layers included in the nitride semiconductor stacked substrates according to the embodiments of the invention are exemplified. The aim of the exemplification is to show principal elements forming these layers, and the exemplification is not intended to show that these layers contain no elements (e.g., impurities) other than the exemplified elements at all.

### First Embodiment

First, a nitride semiconductor stacked substrate according to a first embodiment of the invention and a production method therefor will be described with reference to drawings.

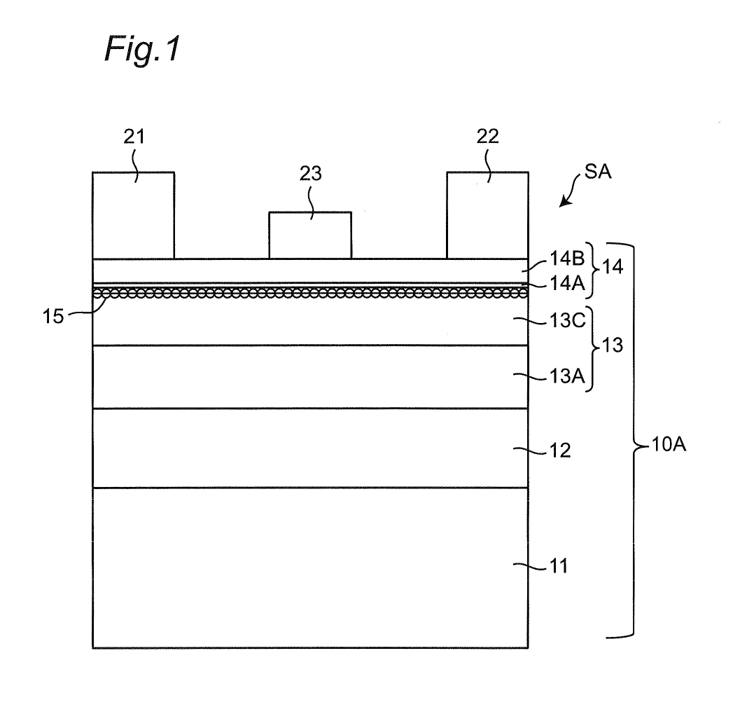

FIG. 1 is a schematic cross-sectional view for illustrating the structure of a switching element SA using the nitride semiconductor stacked substrate 10A according to the first embodiment of the invention,

As shown in FIG. 1, the nitride semiconductor stacked substrate 10A according to the first embodiment of the invention includes a substrate 11, a buffer layer 12 formed on the upper surface of the substrate 11, an electron transit layer 13 formed on the upper surface of the buffer layer 12, and an electron supply layer 14 formed on the upper surface of the electron transit layer 13. The formation of these layers on the substrate 11 is performed in an unillustrated reaction furnace. The lower surface of the electron supply layer 14 is in contact with the upper surface of the electron transit layer 13, and no layer is interposed between the electron transit layer 13 and the electron supply layer 14. The buffer layer 12 is an example of the first nitride semiconductor layer. The electron transit layer 13 is an example of the second nitride semiconductor layer. The electron supply layer 14 is an example of the third nitride semiconductor layer.

The substrate 11 is made of, for example, Si, SiC, Al₂O₃, GaN, AlN, ZnO (zinc oxide), or GaAs (gallium arsenide). The buffer layer 12 is made of, for example, In_{X}Al_{Y}Ga_{1-X-Y}N (wherein 0≦X+Y≦1, 0≦X≦1, and 0≦Y≦1). The substrate 11 and the buffer layer 12 may be made of the same nitride semiconductor. The material of the substrate 11 and the material of the buffer layer 12 are not limited to the materials described above, and any materials may be selected so long as warpage and cracking of the nitride semiconductor stacked substrate 10A can be prevented. For the purpose of improving breakdown voltage, a high-breakdown voltage GaN layer having a carbon concentration of 5×10¹⁶/cm³ or more may be formed above the buffer layer 12.

The electron transit layer 13 is made of, for example, undoped GaN having a thickness of from 1 μm to 5 μm inclusive. The electron transit layer 13 includes a base GaN layer and a channel GaN layer 13C formed on the upper surface of the base GaN layer 13A. The formation conditions of the base GaN layer 13A are different from the formation conditions of the channel GaN layer 130. The carbon concentration of the base GaN layer 13A is less than 5×10¹⁶/cm³. The carbon concentration of the channel GaN layer 13C is 5×10¹⁶/cm³ or more and 1×10¹⁸/cm³ or more. The base GaN layer 13A is an example of the fourth nitride semiconductor layer. The channel GaN layer 13C is an example of the fifth nitride semiconductor layer.

If the carbon concentration of the base GaN layer 13A is 5×10¹⁶/cm³ or more, bending of dislocations, nanopipes, etc. 15 small at the interface between the base GaN layer 13A and the buffer layer 12, and these dislocations, nanopipes, etc. extend to a two-dimensional electron gas region, so that the device characteristics are adversely affected. Also in the case in which the high-breakdown voltage GaN layer is formed above the buffer layer 12, if the carbon concentration of the base GaN layer 13A is 5×10¹⁶/cm³ or more, bending of dislocations, nanopipes, etc. is small at the interface between the base GaN layer 13A and the high-breakdown voltage GaN layer.

Although the detailed reason is unclear, if the carbon concentration of the channel GaN layer 13C is less than 5×10¹⁶/cm³, the flatness of the interface between the channel GaN layer 13C and a spacer layer 14A decreases, and the mobility of electrons in the two-dimensional electron gas region decreases. If the carbon concentration of the channel GaN layer 13C is 1×10¹⁸/cm³ or more, the excessive amount of carbon causes deterioration of the flatness of the interface between the channel GaN layer 13C and the spacer layer 14A, so that the mobility of electrons in the two-dimensional electron gas region decreases. When no spacer layer 14A is disposed between the channel GaN layer 13C and a barrier layer 14B, the flatness of the interface between the channel GaN layer 13C and the barrier layer 14B deteriorates.

The electron supply layer 14 includes the spacer layer 14A made of AlN of, for example, 5 nm or less and the barrier layer 14B made of Al_{Z}Ga_{1-z}N (0<Z<1) of, for example, from 5 nm to 100 nm inclusive. The band gap of the spacer layer 14A is larger than the band gaps of the base GaN layer 13A and the channel GaN layer 13C. The band gap of the barrier layer 14B is also larger than the band gaps of the base GaN layer 13A and the channel GaN layer 13C. Specifically, the electron supply layer 14 has a larger band gap than the electron transit layer 13. It is more preferable that the composition ratio Z in the Al_{Z}Ga_{1-Z}N satisfies 0.1≦Z≦0.5.

The switching element SA includes the nitride semiconductor stacked substrate 10A, a source electrode 21, a drain electrode 22, and a gate electrode 23.

The source electrode 21, the drain electrode 22, and the gate electrode 23 are formed on the upper surface of the electron supply layer 14. The gate electrode 23 is disposed between the source electrode 21 and the drain electrode 22.

Each of the source electrode 21, the drain electrode 22, and the gate electrode 23 is made of a metal element such as Ti, Al, Cu, Au, Pt, W, Ta, Ru, Ir, Pd, or Hf, an alloy containing at least two of these metal elements, or a nitride containing at least one of these metal elements. Each of the source electrode 21, the drain electrode 22, and the gate electrode 23 may be composed of a single layer or may be composed of a plurality of layers with different compositions.

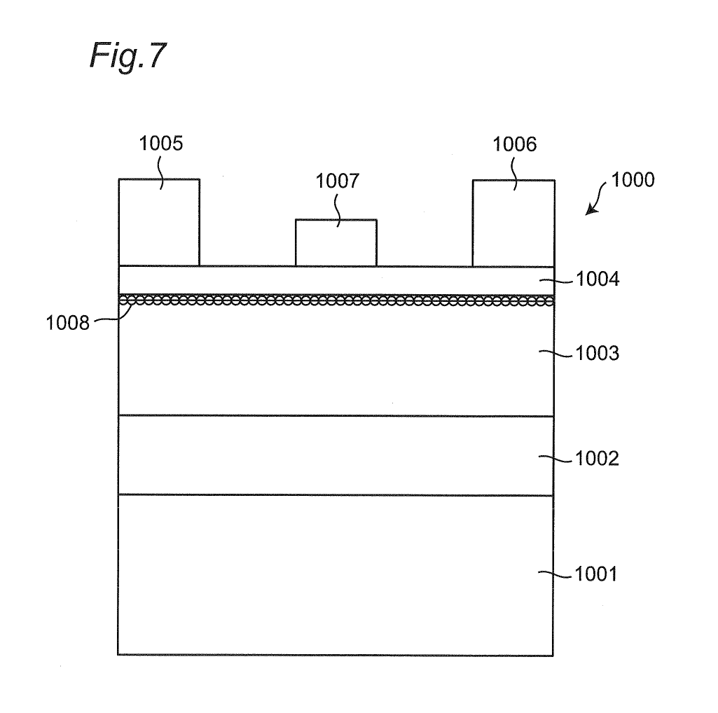

The switching element SA is of the normally-on type. Therefore, when the potential of the gate electrode 23 is the same as the potential of the source electrode 21 or when the gate electrode 23 is open, a two-dimensional electron gas layer 15 is formed in the vicinity of the interface between the channel GaN layer 13C and the spacer layer 14A, and the switching element SA is in an ON state. In the switching element SA in the ON state, electric current flows between the source electrode 21 and the drain electrode 22 when the potential of the drain electrode 22 is higher than the potential of the source electrode 21. Meanwhile, when the potential of the gate electrode 23 is lower than a threshold voltage with respect to the potential of the source electrode 21, the two-dimensional electron gas layer 15 is not formed in a region below the gate electrode 23 and in the vicinity of the interface between the channel GaN layer 13C and the spacer layer 14A. Specifically, the same region as the depletion region 1009 in FIG. 7 is formed below the gate electrode 23, and the switching element SA is in an OFF state. When the switching element SA is in the OFF state, no electric current flows between the source electrode 21 and the drain electrode 22.

In the nitride semiconductor stacked substrate 10A, it is necessary to form the electron supply layer 14 on the upper surface of the electron transit layer 13 made of GaN, as described above. Suppose that, after the formation of the electron transit layer 13, the temperature of the substrate is increased, the pressure inside the furnace (the internal pressure of the reaction furnace containing the substrate 11) is reduced, and then the formation of the electron supply layer 14 is started. In this case, while the substrate temperature is increased and the furnace pressure is reduced, the GaN forming the electron transit layer 13 undergoes thermal decomposition. Therefore, irregularities are formed on the upper surface (interface) of the electron transit layer 13.

In the nitride semiconductor stacked substrate 10A according to the first embodiment of the invention, the electron transit layer 13 and the electron supply layer 14 are formed such that the thermal decomposition of the GaN forming the electron transit layer 13 can be prevented. This will next be described with reference to a drawing.

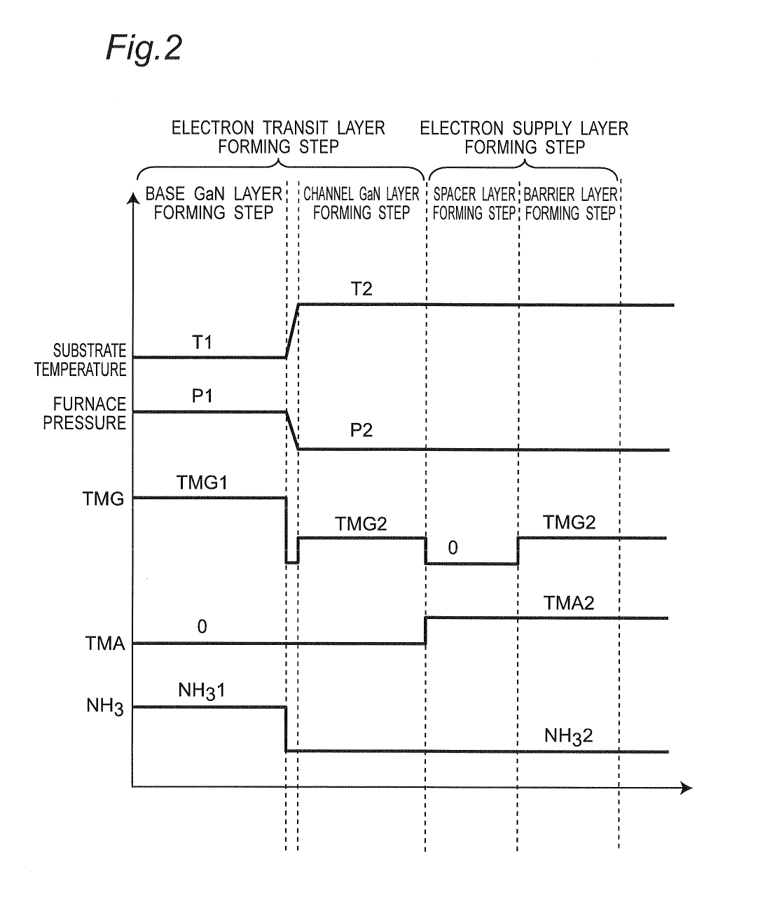

FIG. 2 is a sequence diagram showing changes in the substrate temperature, the furnace pressure, and the feed amounts of raw material gasses in an electron transit layer forming step and an electron supply layer forming step. In the electron transit layer forming step and the electron supply layer forming step, the electron transit layer 13 and the electron supply layer 14 are formed by an MOCVD method. The electron transit layer forming step and the electron supply layer forming step are performed sequentially within the reaction furnace after a buffer layer forming step of forming the buffer layer 12 on the upper surface of the substrate 11 within the reaction furnace. The horizontal axis of the FIG. 2 represents time, and the time on the horizontal axis increases toward the right of FIG. 2. The vertical axis of FIG. 2 represents the substrate temperature, the furnace pressure, or the feed amounts of the raw material gasses. When the vertical axis of FIG. 2 represents the substrate temperature, the substrate temperature on the vertical axis increases toward the top of FIG. 2. When the vertical axis of FIG. 2 represents the furnace pressure, the furnace pressure on the vertical axis increases toward the top of FIG. 2. When the vertical axis of FIG. 2 represents the feed amounts of the raw material gasses, the feed amounts of the raw material gasses on the vertical axis increase toward the top of FIG. 2. The buffer layer forming step is an example of the first nitride semiconductor layer forming step. The electron transit layer forming step is an example of the second nitride semiconductor layer forming step. The electron supply layer forming step is an example of the third nitride semiconductor layer forming step.

As shown in FIG. 2, first, the base GaN layer 13A made of GaN is formed on the buffer layer 12 (a base GaN layer forming step). Specifically, TMG (trimethylgallium), which is the raw material of Ga, and NH₃, which is the raw material of N, are supplied to the reaction furnace to form the base GaN layer 13A made of GaN. In this case, H₂ is used as a carrier gas. The substrate temperature is set to T1, and the furnace pressure is set to P1. The substrate temperature T1 is, for example, from 600° C. to 1,300° C. inclusive and more preferably from 700° C. to 1,200° C. inclusive. The furnace pressure P1 is, for example, 0.15 atm or higher. The base GaN layer forming step is an example of the fourth nitride semiconductor layer forming step.

After completion of the formation of the base GaN layer 13A, the supply of TMG is stopped, and the formation conditions are changed to those for a channel GaN layer forming step. In this case, the substrate temperature is changed from T1 to T2, and the furnace pressure is changed from P1 to P2. T2 is higher than T1 and is, for example, from 900° C. to 1,400° C. inclusive and more preferably from 900° C. to 1,200° C. inclusive. P2 is lower than P1 and is, for example, 0.15 atm or less. As for the feed amounts of TMG and NH₃ used as raw material gasses, it is preferable that TMG2<TMG1 and NH₃2<NH₃1. Here, TMG1 and NH₃1 are the feed amounts of TMG and NH₃, respectively, in the base GaN layer forming step, and TMG2 and NH₃2 are the feed amounts of TMG and NH₃, respectively, in the channel GaN layer forming step. This is because since the electron supply layer 14 is much thinner than the electron transit layer 13, the growth rate of the electron transit layer 13 is reduced to stabilize the quality of the film. The channel GaN layer forming step is an example of the fifth nitride semiconductor layer forming step.

After the substrate temperature, the furnace pressure, the feed amount of TMG, and the feed amount of NH₃ are stabilized at T2, P2, TMG2, and NH₃2, respectively, the channel GaN layer 130 is formed (the channel GaN layer forming step). The carbon concentration of the channel GaN layer 130 tends to be larger than that of the base GaN layer 13A because of the influence of the reduction in pressure from P1 to P2.

After completion of the formation of the channel GaN layer 130, the supply of TMG is stopped, and the supply of TMA (trimethylaluminum) used as the material of Al is started while the feed amount of NH₃, the substrate temperature, and the furnace pressure are maintained at NH₃2, T2, and P2, respectively, and the spacer layer 14A is thereby formed (a spacer layer forming step). At the time of the start of the formation of the spacer layer 14A, the substrate temperature T2 and the furnace pressure P2 have been set to conditions suitable for the formation of the spacer layer 14A and the barrier layer 14B. Therefore, it is unnecessary to interrupt the formation in order to perform particularly time-consuming adjustment of the substrate temperature and the furnace pressure.

After completion of the formation of the spacer layer 14A, the supply of TMG is resumed to form the barrier layer 14B (a barrier layer forming step). In this case, it is preferable that the feed amount of TMG is set to TMG2 that is the same as the feed amount of TMG in the channel GaN layer forming step. This is because the feed amount of TMG in the steps from the channel GaN layer forming step to the barrier layer forming step can be controlled by simply opening and closing a valve without changing the setting of a mass flow controller.

As described above, in the nitride semiconductor stacked substrate 10A according to the first embodiment of the invention, the substrate temperature and the furnace pressure are changed to those for the electron supply layer 14 at an intermediate point during the formation of the electron transit layer 13. In this manner, no interval is provided between the electron transit layer forming step and the electron supply layer forming step, and the electron supply layer forming step can be performed continuously after the electron transit layer forming step. The thermal decomposition of GaN on the upper surface of the electron transit layer 13 is thereby prevented, and irregularities are unlikely to be formed on the upper surface (interface) of the electron transit layer 13. Therefore, the surface roughness (e.g., the arithmetic mean roughness Ra) of the nitride semiconductor stacked substrate 10A measured by an atomic force microscope in a 1 μm×1 μm scanning area, i.e., the surface roughness (e.g., the arithmetic mean roughness Ra) of the upper surface of the barrier layer 14B measured by the atomic force microscope, is 0.5 nm or less.

The spacer layer 14A has a very small thickness of, for example, 5 nm or less. By preventing the formation of irregularities on the upper surface (interface) of the electron transit layer 13, the thickness of the very thin spacer layer 14A can be made uniform. In this case, the states of the electron transit layer 13 and the spacer layer 14A in in-plane directions are made uniform. Therefore, the deterioration of the characteristics of the switching element SA such as a reduction in the mobility of electrons in the two-dimensional electron gas 15 can be prevented.

In the first embodiment, the buffer layer 12 is formed on the upper surface of the substrate 11. However, the buffer layer may be formed above the substrate 11. Specifically, the buffer layer may be formed on the substrate 11 through another layer.

In the first embodiment, the electron supply layer 14 may include a barrier layer made of In_{J}Al_{L}Ga_{1-J-L}N (wherein 0<J+L≦1, 0≦J<1, and 0<L≦1) instead of the barrier layer 14B made of Al_{Z}Ga_{1-Z}N (0<Z<1).

### Second Embodiment

Next, a nitride semiconductor stacked substrate according to a second embodiment of the invention and a production method therefor will be described with reference to drawings.

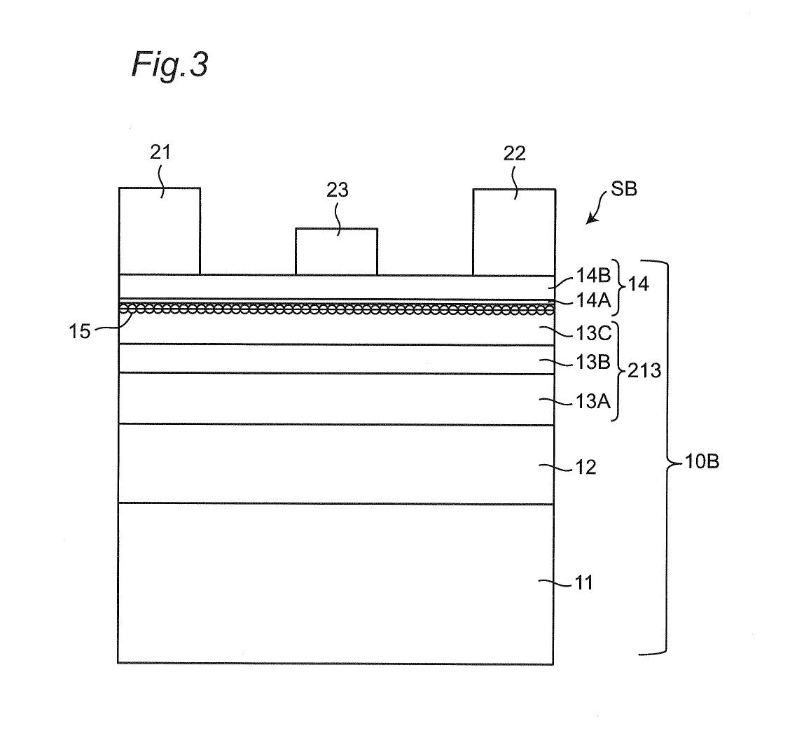

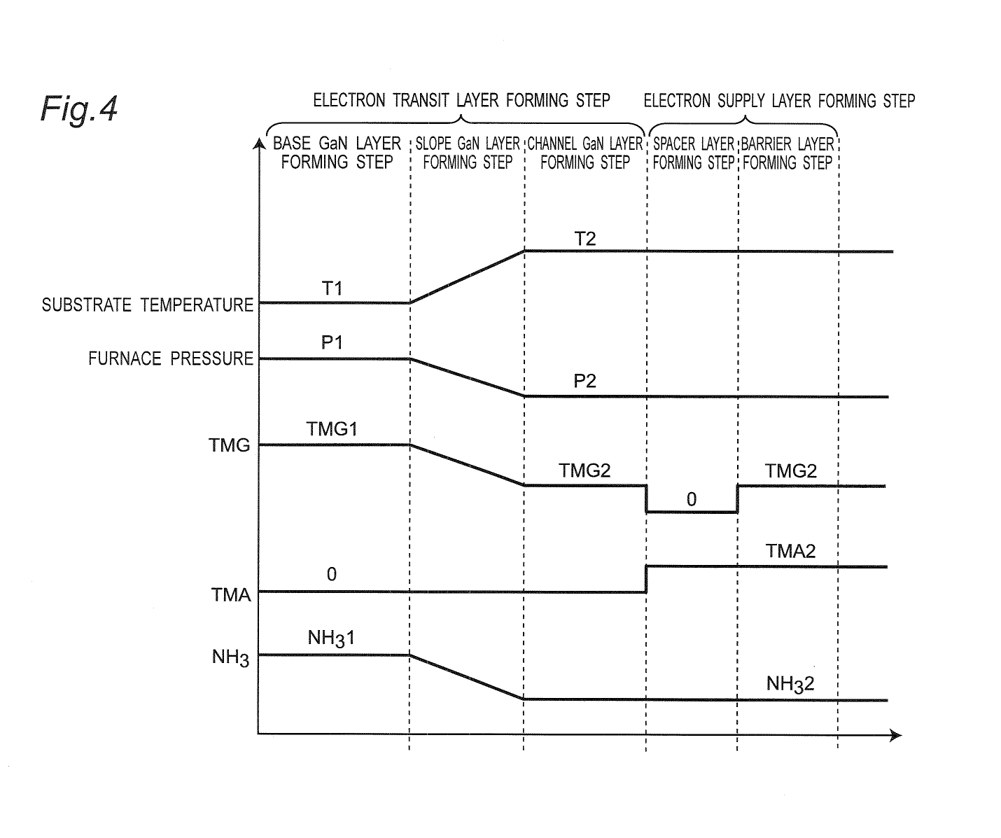

FIG. 3 is a schematic cross-sectional view for illustrating the structure of a switching element SB using the nitride semiconductor stacked substrate 10B according to the second embodiment of the invention. FIG. 4 is a sequence diagram showing changes in substrate temperature, furnace pressure, and the feed amounts of raw material gasses in an electron transit layer forming step and an electron supply layer forming step for the nitride semiconductor stacked substrate 10B. The structure of the nitride semiconductor stacked substrate 10B according to the second embodiment of the invention and the production method therefor are shown in FIGS. 3 and 4 in the same manner as in FIGS. 1 and 2 in the first embodiment. In the following description of the nitride semiconductor stacked substrate 10B, repeated description of the same components as those in the first embodiment may be omitted.

As shown in FIG. 3, the nitride semiconductor stacked substrate 10B according to the second embodiment of the invention includes a substrate 11, a buffer layer 12 formed on the upper surface of the substrate 11, an electron transit layer 213 formed on the upper surface of the buffer layer 12, and an electron supply layer 14 formed on the upper surface of the electron transit layer 213.

The switching element SB includes the nitride semiconductor stacked substrate 10B, a source electrode 21, a drain electrode 22, and a gate electrode 23.

The source electrode 21, the drain electrode 22, and the gate electrode 23 are formed on the upper surface of the electron supply layer 14. The gate electrode 23 is disposed between the source electrode 21 and the drain electrode 22.

The nitride semiconductor stacked substrate 10B is different from the nitride semiconductor stacked substrate 10A in the first embodiment in that the electron transit layer 213 includes a base GaN layer 13A, a slope GaN layer 13B, and a channel GaN layer 13C. The formation conditions of the base GaN layer 13A, the formation conditions of the slope GaN layer 13B, and formation conditions of the channel GaN layer 13C are different from each other. The band gap of a spacer layer 14A is larger than the band gaps of the base GaN layer 13A, the slope GaN layer 13B, and the channel GaN layer 13C. The band gap of a barrier layer 14B is also larger than the band gaps of the base GaN layer 13A, the slope GaN layer 13B, and the channel GaN layer 13C. Specifically, the electron supply layer 14 has a larger band gap than the electron transit layer 213. The slope GaN layer 133 is an example of the sixth nitride semiconductor layer.

The slope GaN layer 13B is a layer that can be formed by continuing the supply of TMG and NH₃ to the reaction furnace in the transition step in the first embodiment in which the formation conditions are changed from those for the base GaN layer forming step to those for the channel GaN forming step.

Next, a method for forming the electron transit layer 213 and electron supply layer 14 of the nitride semiconductor stacked substrate 10B will be described specifically using FIG. 4.

As shown in FIG. 4, first, the base GaN layer 13A is formed on the buffer layer 12 using the same formation method as the method for forming the base GaN layer 13A in the first embodiment (a base GaN forming step).

After completion of the formation of the base GaN layer 13A, the substrate temperature etc, are changed to those for the formation of the channel GaN layer 13C. In this case, the substrate temperature, the furnace pressure, the feed amount of TMG, and the feed amount of NH₃ are gradually changed from T1 to T2, from P1 to P2, from TMG1 to TMG2, and from NH₃1 to NH₃2, respectively, in a given time. During the changes, TMG and NH₃ are continuously supplied to the reaction furnace, and the slope GaN layer 13B is thereby formed (a slope GaN layer forming step). In the vicinity of the interface between the base GaN 13A and the slope GaN layer 13B, the carbon concentration of the slope GaN layer 13B is substantially the same as the carbon concentration of the base GaN 13A. In the vicinity of the interface between the channel GaN layer 13C and the slope GaN layer 13B, the carbon concentration of the slope GaN layer 13B is substantially the same as the carbon concentration of the channel GaN layer 13C. The carbon concentration of the slope GaN layer 13B gradually increases from a lower portion of the slope GaN layer 13B to its upper portion.

After completion of the formation of the slope GaN layer 13B, while the feed amount of TMG, the feed amount of NH₃, the substrate temperature, and the furnace pressure are maintained at TMG2, NH₃2, T2, and P2, respectively, the channel GAN layer 13C is formed (a channel GaN layer forming step). In this case, the carbon concentration of the channel GaN layer 13C tends to be larger than that of the base GaN layer 13A because of the influence of the reduction in pressure from P1 to P2.

After completion of the formation of the channel GaN layer 13C, the supply of TMG is stopped, and the supply of TMA is started to thereby form the spacer layer 14A in the same manner as in the method for forming the spacer layer 14A in the first embodiment (a spacer layer forming step). At the time of completion of the formation of the channel GaN layer 13C, the substrate temperature is T2, and the furnace pressure is P2. The substrate temperature T2 and the furnace pressure 22 are suitable for the formation of the spacer layer 14A and the barrier layer 14B. Therefore, after the formation of the channel GaN layer 13C, the spacer layer 14A is formed continuously with no interval.

After completion of the formation of the spacer layer 14A, the supply of TMG is resumed to form the barrier layer 14B in the same manner as in the method for forming the barrier layer 14B in the first embodiment (a barrier layer forming step). In this case, it is preferable that the feed amount of TMG is set to TMG2 that is the feed amount of TMG in the channel GaN layer forming step. This is because the feed amount of TMG in the steps from the channel GaN layer forming step to the barrier layer forming step can be controlled by simply opening and closing a valve without changing the setting of a mass flow controller.

As described above, in the nitride semiconductor stacked substrate 10B according to the second embodiment of the invention, the substrate temperature and the furnace pressure are changed to those for the electron supply layer 14 at an intermediate point during the formation of the electron transit layer 213 in the same manner as in the first embodiment. In this manner, no interval is provided between the electron transit layer forming step and the electron supply layer forming step, and the electron supply layer forming step can be performed continuously after the electron transit layer forming step. The thermal decomposition of GaN on the upper surface of the electron transit layer 13 is thereby prevented, and irregularities are unlikely to be formed on the upper surface (interface) of the electron transit layer 13. Therefore, the surface roughness (e.g., the arithmetic mean roughness Ra) of the nitride semiconductor stacked substrate 10A measured by an atomic force microscope in a 1 μm×1 μm scanning area, i.e., the surface roughness (e.g., the arithmetic mean roughness Re) of the upper surface the barrier layer 14B measured by the atomic force microscope, is 0.5 nm or less.

The spacer layer 14A has a very small thickness of, for example, 5 nm or less. By preventing the formation of irregularities on the upper surface (interface) of the electron transit layer 213, the thickness of the very thin spacer layer 14A can be made uniform. In this case, the states of the electron transit layer 213 and the spacer layer 14A in in-plane directions are made uniform. Therefore, the deterioration of the characteristics of the switching element SB such as a reduction in the mobility of electrons can be prevented.

By forming the slope GaN layer 13B between the base GaN layer 13A and the channel GaN layer 130, irregularities inside the electron transit layer 213 are reduced. Therefore, the adverse effects of the electron transit layer 213 on the crystallinity and defects of the electron supply layer 14 can be reduced.

In the slope GaN layer forming step, the substrate temperature, the furnace pressure, and the feed amounts of the raw material gasses are gradually changed. Therefore, overshoot or undershoot of the substrate temperature, the furnace pressure, and the feed amounts of the raw material gasses is prevented from occurring.

### Third Embodiment

Next, a nitride semiconductor stacked substrate according to a third embodiment of the invention and a production method therefor will be described with reference to drawings.

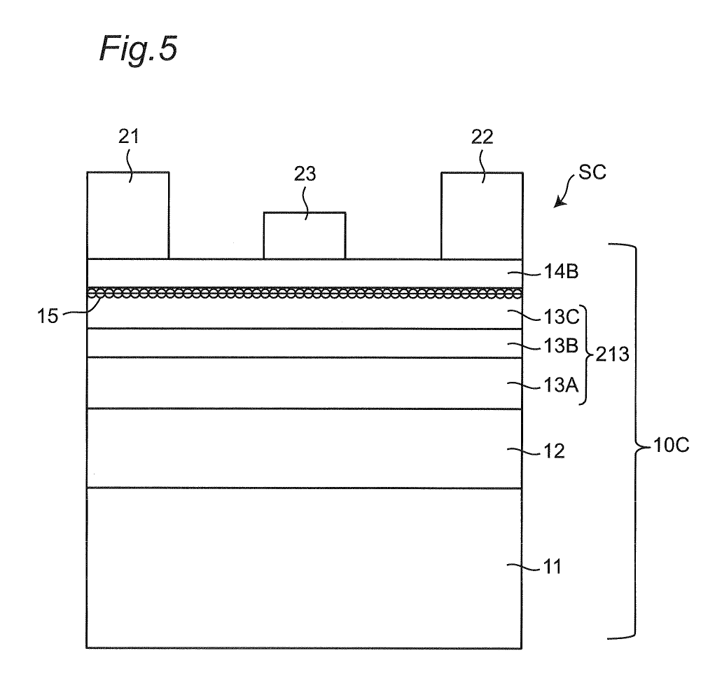

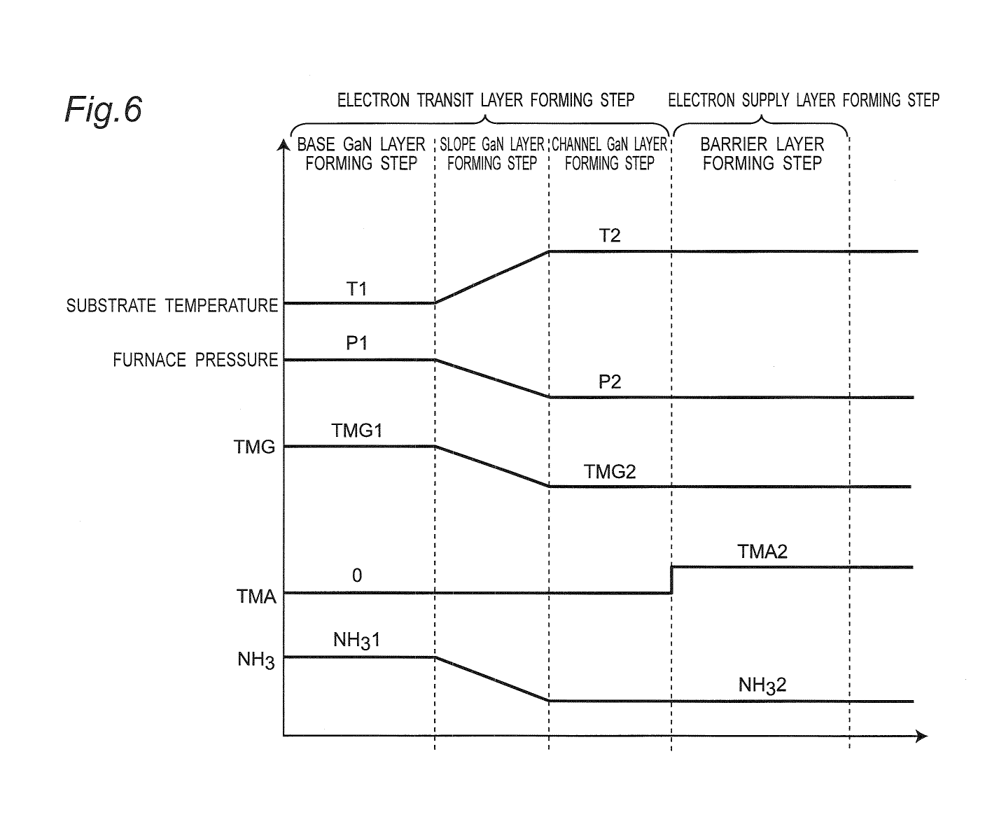

FIG. 5 is a schematic toss-sectional view for illustrating the structure of a switching element SC using the nitride semiconductor stacked substrate 10C according to the third embodiment of the invention. FIG. 6 is a sequence diagram showing changes in substrate temperature, furnace pressure, and the feed amounts of raw material gasses in an electron transit layer forming step and an electron supply layer forming step for the nitride semiconductor stacked substrate 100. The structure of the nitride semiconductor stacked substrate 100 according to the third embodiment of the invention and the production method therefor are shown in FIGS. 5 and 6 in the same manner as in FIGS. 1 and 2 in the first embodiment. In the following description of the nitride semiconductor stacked substrate 100, repeated description of the same components as those in the first embodiment may be omitted.

As shown in FIG. 5, the nitride semiconductor stacked substrate 100 according to the third embodiment of the invention includes a substrate 11, a buffer layer 12 formed on the upper surface of the substrate 11, an electron transit layer 13 formed on the upper surface of the buffer layer 12, and a barrier layer 14B formed on the upper surface of the electron transit layer 13. The lower surface of the barrier layer 14B is in contact with the upper surface of the electron transit layer 13, and no layer is interposed between the electron transit layer 13 and the barrier layer 14B. The barrier layer 14B is an example of the third nitride semiconductor layer.

The switching element SC includes the nitride semiconductor stacked substrate 10C, a source electrode 21, a drain electrode 22, and a gate electrode 23.

The source electrode 21, the drain electrode 22, and the gate electrode 23 are formed on the upper surface of the barrier layer 143. The gate electrode 23 is disposed between the source electrode 21 and the drain electrode 22.

The nitride semiconductor stacked substrate 10C is different from the nitride semiconductor stacked substrate 10A in the first embodiment in that the electron transit layer 213 includes a base GaN layer 13A, a slope GaN layer 13B, and a channel GaN layer 13C and that only the barrier layer 143 forms an electron supply layer.

Next, a method for forming the electron transit layer 213 and electron supply layer 14 of the nitride semiconductor stacked substrate 103 will be described specifically using FIG. 5.

As shown in FIG. 6, first, the base GaN layer 13A is formed on the buffer layer 12 using the same formation method as the method for forming the base GaN layer 13A in the second embodiment (a base GaN forming step).

After completion of the formation the base GaN layer 13A, the substrate temperature etc. are changed to those for the formation of the channel GaN layer 13C. In this case, the substrate temperature, the furnace pressure, the feed amount of TMG, and the feed amount of NH₃ are gradually changed from T1 to T2, from P1 to P2, from TMG1 to TMG2, and from NH₃1 to NH₃2, respectively, in a given time. During the changes, TMG and NH₃ are continuously supplied to the reaction furnace, and the slope GaN layer 130 is thereby formed (a slope GaN layer forming step). In the vicinity of the interface between the base GaN 13A and the slope GaN layer 13B, the carbon concentration of the slope GaN layer 13B is substantially the same as the carbon concentration of the base GaN 13A. In the vicinity of the interface between the channel GaN layer 13C and the slope GaN layer 13B, the carbon concentration of the slope GaN layer 13B is substantially the same as the carbon concentration of the channel GaN layer 13C. The carbon concentration of the slope GaN layer 130 gradually increases from a lower portion of the slope GaN layer 13B to its upper portion.

After completion of the formation of the slope GaN layer 13B, while the feed amount of TMG, the feed amount of NH₃, the substrate temperature, and the furnace pressure are maintained at TMG2, NH₃2, T2, and P2, respectively, the channel GAN layer 13C is formed (a channel GaN layer forming step). In this case, the carbon concentration of the channel GaN layer 13C tends to be larger than that of the base GaN layer 13A because of e influence of the reduction in pressure from P1 to P2.

After completion of the formation of the channel GaN layer 13C, while the feed amount of TMG, the feed amount of NH₃, the substrate temperature, and the furnace pressure are maintained at TMG2, NH₃2, T2, and P2, respectively, the supply of TMA used as the material of Al is started to thereby form the barrier layer 14B serving as the electron supply layer (a barrier layer forming step). In this case, it is preferable that the feed amount of TMG is set to TMG2 that is the feed amount of TMG in the channel GaN layer forming step. This is because the feed amount of TMG in the steps from the channel GaN layer forming step to the barrier layer forming step can be controlled by simply opening and closing a valve without changing the setting of a mass flow controller.

As described above, in the nitride semiconductor stacked substrate 10C according to the second embodiment of the invention, the substrate temperature and the furnace pressure are changed to those for the electron supply layer 14 at an intermediate point during the formation of the electron transit layer 213 in the same manner as in the first embodiment. In this manner, no interval is provided between the electron transit layer forming step and the electron supply layer forming step, and the electron supply layer forming step can be performed continuously after the electron transit layer forming step. The thermal decomposition of GaN on the upper surface of the electron transit layer 13 is thereby prevented, and irregularities are unlikely to be formed on the upper surface (interface) of the electron transit layer 13. Therefore, the surface roughness (e.g., the arithmetic mean roughness Ra) of the nitride semiconductor stacked substrate 10A measured by an atomic force microscope in a 1 μm×1 μm scanning area, i.e., the surface roughness (e.g., the arithmetic mean roughness Ra) of the upper surface the barrier layer 14B measured by the atomic force microscope, is 0.5 nm or less.

The spacer layer 14A has a very small thickness of, for example, 5 nm or less. By preventing the formation of irregularities on the upper surface (interface) of the electron transit layer 213, the thickness of the very thin spacer layer 14A can be made uniform. In this case, the states of the electron transit layer 213 and the spacer layer 14A in in-plane directions are made uniform. Therefore, the deterioration of the characteristics of the switching element SB such as a reduction in the mobility of electrons can be prevented.

By forming the slope GaN layer 132 between the base GaN layer 13A and the channel GaN layer 13C, irregularities inside the electron transit layer 213 are reduced. Therefore, the adverse effects of the electron transit layer 213 on the crystallinity and defects of the electron supply layer 14 can be reduced.

In the slope GaN layer forming step, the substrate temperature, the furnace pressure, and the feed amounts of the raw material gasses are gradually changed. Therefore, overshoot or undershoot of the substrate temperature, the furnace pressure, and the feed amounts of the raw material gasses is prevented from occurring.

By reducing the irregularities on the upper surface of the electron transit layer 213, the mobility of electrons in the two-dimensional electron gas layer 1008 is improved. Therefore, although the nitride semiconductor stacked substrate 10C does not include the spacer layer 14A in the first embodiment, the ON resistance of the switching element SC is sufficiently low.

If the spacer layer 14A is formed between the electron transit layer 213 and the barrier layer 14B, the lattice mismatch between the electron transit layer 213 and the spacer layer 14A becomes large, and the piezoelectric effect increases accordingly. However, this causes an adverse effect on long-term stability. Therefore, it is highly significant that the spacer layer 14A causing a reliability risk can be eliminated.

The specific embodiments of the invention have been described. However, the invention is not limited to the above first to third embodiments, and various modifications are possible within the scope of the invention. For example, an appropriate combination of the configurations described in the above first to third embodiments may be used as an embodiment of the invention.

The invention and the embodiments are summarized as follows.

The nitride semiconductor stacked body production method of the invention comprises:

a first nitride semiconductor layer forming step of forming a first nitride semiconductor layer 12 above a substrate 11 within a reaction furnace;

a second nitride semiconductor layer forming step of forming a second nitride semiconductor layer 13, 213 above the first nitride semiconductor layer 12; and

a third nitride semiconductor layer forming step of forming a third nitride semiconductor layer 14, 14B on an upper surface of the second nitride semiconductor layer 13, 213, the third nitride semiconductor layer 14, 14B having a band gap larger than a band gap of the second nitride semiconductor layer 13, 213,

wherein no interval is provided between the second nitride semiconductor layer forming step and the third nitride semiconductor layer forming step, and the third nitride semiconductor layer forming step is performed continuously after the second nitride semiconductor layer forming step.

In the above configuration, no interval is provided between the second nitride semiconductor layer forming step and the third nitride semiconductor layer forming step, and the third nitride semiconductor layer forming step is performed continuously after the second nitride semiconductor layer forming step. Therefore, the formation of irregularities on the upper surface of the second nitride semiconductor can be prevented.

In one embodiment of the nitride semiconductor stacked body production method,

the second nitride semiconductor layer forming step includes:

a fourth nitride semiconductor layer forming step of forming a fourth nitride semiconductor layer 13A; and

a fifth nitride semiconductor layer forming step of forming a fifth nitride semiconductor layer 13C above the fourth nitride semiconductor layer 13A,

wherein a temperature of the substrate in the fifth nitride semiconductor layer forming step is higher than the temperature of the substrate in the fourth nitride semiconductor layer forming step, and

wherein a pressure inside the furnace in the fifth nitride semiconductor layer forming step is lower than the pressure inside the furnace in the fourth nitride semiconductor layer forming step.

In the above embodiment, the substrate temperature is relatively high in the latter half of the second nitride semiconductor layer forming step, and the furnace pressure is relatively low in the latter half. Therefore, even when the third nitride semiconductor layer 14, 14B is formed at high substrate temperature and low furnace pressure, the second nitride semiconductor layer forming step and the third nitride semiconductor layer forming step can be performed continuously in a preferable manner.

In another embodiment of the nitride semiconductor stacked body production method,

the second nitride semiconductor layer forming step further includes a sixth nitride semiconductor layer forming step of forming a sixth nitride semiconductor layer 13B between the fourth nitride semiconductor layer 13A and the fifth nitride semiconductor layer 13C,

wherein the temperature of the substrate in the sixth nitride semiconductor layer forming step gradually changes from the temperature of the substrate in the fourth nitride semiconductor layer forming step to the temperature of the substrate in the fifth nitride semiconductor layer forming step, and

wherein the pressure inside the furnace in the sixth nitride semiconductor layer forming step gradually changes from the pressure inside the furnace in the fourth nitride semiconductor layer forming step to the pressure inside the furnace in the fifth nitride semiconductor layer forming step.

In the above embodiment, the substrate temperature and the furnace pressure change gradually in the sixth nitride semiconductor layer forming step. Therefore, defects in the second nitride semiconductor layer 13, 213 can be reduced, and the crystallinity of the second nitride semiconductor layer 13, 213 can be improved.

Since the substrate temperature and the furnace pressure change gradually in the sixth nitride semiconductor layer forming step, overshoot or undershoot of the substrate temperature and the furnace temperature can be prevented from occurring when the fifth nitride semiconductor layer forming step is started.

In another embodiment of the nitride semiconductor stacked body production method,

the second nitride semiconductor layer 13, 213 is made of GaN, and
the third nitride semiconductor layer 14B is made of AlₓGa₁₋ₓN (0<x<1).

In the above embodiment, since the lattice mismatch between the second nitride semiconductor layer 13, 213 and the third nitride semiconductor layer 14B is small, an improvement in long-term reliability can be achieved.

The nitride semiconductor stacked body of the invention comprises:

a substrate 11;

a first nitride semiconductor layer 12 formed above the substrate 11;

a second nitride semiconductor layer 13, 213 formed above the first nitride semiconductor layer 12; and

a third nitride semiconductor layer 14, 142 formed on an upper surface of the second nitride semiconductor layer 13, 213 and having a band gap larger than a band gap of the second nitride semiconductor layer 13, 213,

wherein the second nitride semiconductor layer 13, 213 and the third nitride semiconductor layer 14, 142 are formed such that no interval is provided between formation of the second nitride semiconductor layer 13, 213 and formation of the third nitride semiconductor layer 14, 14B and that the formation of the third nitride semiconductor layer 14, 14B is performed continuously after the formation of the second nitride semiconductor layer 13, 213.

In the above configuration, the second nitride semiconductor layer 13, 213 and the third nitride semiconductor layer 14, 14B are formed such that no interval is provided between the formation of the second nitride semiconductor layer 13, 213 and the formation of the third nitride semiconductor layer 14, 14B and that the formation of the third nitride semiconductor layer 14, 14B is performed continuously after the formation of the second nitride semiconductor layer 13, 213. Therefore, the formation of irregularities on the upper surface of the second nitride semiconductor can be prevented.

In one embodiment of the nitride semiconductor stacked body,

the second nitride semiconductor layer 13, 213 includes:

a fourth nitride semiconductor layer 13A having a carbon concentration of less than 5×10¹⁶/cm³; and

a fifth nitride semiconductor layer 13C formed above the fourth nitride semiconductor layer and having a carbon concentration of 5×10¹⁶/cm³ or more and less than 1×10¹⁸/cm³.

In the above embodiment, since the carbon concentration of the fourth nitride semiconductor layer 13A is less than 5×10¹⁶/cm³, dislocations, nanopipes, etc. formed at the interface between the first nitride semiconductor layer 12 and the fourth nitride semiconductor layer 13A are prevented from adversely affecting device characteristics.

Since the carbon concentration of the fifth nitride semiconductor layer 13C is 5×10¹⁶/cm³ or more and less than 1×10¹⁸/cm³, a reduction in the flatness of the interface between the fifth nitride semiconductor layer 13C and the third nitride semiconductor layer 14, 143 can be prevented.

In another embodiment of the nitride semiconductor stacked body, the second nitride semiconductor layer 13, 213 further includes a sixth nitride semiconductor layer 13B formed between the fourth nitride semiconductor layer 13A and the fifth nitride semiconductor layer 130, and

the sixth nitride semiconductor layer 132 has a carbon concentration that gradually increases from a lower portion of the sixth nitride semiconductor layer 13B to an upper portion of the sixth nitride semiconductor layer 13B, the carbon concentration of the sixth nitride semiconductor layer 13B in the vicinity of an interface between the fourth nitride semiconductor layer 13A and the sixth nitride semiconductor layer 13B being substantially the same as the carbon concentration of the fourth nitride semiconductor layer 13A, the carbon concentration of the sixth nitride semiconductor layer 132 in the vicinity of an interface between the fifth nitride semiconductor layer 130 and the sixth nitride semiconductor layer 13B being substantially the same as the carbon concentration of the fifth nitride semiconductor layer 130.

In the above embodiment, the carbon concentration gradually increases from the carbon concentration substantially the same as that of the fourth nitride semiconductor layer 13A to the carbon concentration substantially the same as that of the fifth nitride semiconductor layer 13C. Therefore, the formation conditions can be gradually changed from those of the fourth nitride semiconductor layer 13A to those of the fifth nitride semiconductor layer 130. This allows defects in the second nitride semiconductor layer 13, 213 can be reduced, and the crystallinity of the second nitride semiconductor layer 13, 213 can be improved.

Since the formation conditions can be gradually changed from those of the fourth nitride semiconductor layer 13A to those of the fifth nitride semiconductor layer 13C, overshoot or undershoot of the substrate temperature and the furnace temperature can be prevented from occurring when the formation of the fifth nitride semiconductor layer 13C is started.

In another embodiment of the nitride semiconductor stacked body,

the second nitride semiconductor layer 13, 213 is made of GaN, and

the third nitride semiconductor layer 14B is made of AlₓGa₁₋N (0<x<1).

In the above embodiment, since the lattice mismatch between the second nitride semiconductor layer 13, 213 and the third nitride semiconductor layer 14B is small, an improvement in long-term reliability can be achieved.

In another embodiment of the nitride semiconductor stacked body,

an upper surface of the third nitride semiconductor layer 14, 14B has a surface roughness of 0.5 nm or less as measured by an atomic force microscope in a 1 μm×1 μm scanning area.

In the above embodiment, when, for example, a source electrode 21, a drain electrode 22, and a gate electrode 23 are formed on the upper surface of the third nitride semiconductor layer 14, 14B, the adhesion of the source electrode 21, the drain electrode 22, and the gate electrode 23 to the upper surface of the third nitride semiconductor layer 14, 14B can be improved.

### REFERENCE SIGNS LIST

10A, 10B, 10C nitride semiconductor stacked substrate
11 substrate
12 buffer layer
13, 213 electron transit layer
13A base GaN layer
13B slope GaN layer
13C channel GaN layer
14 electron supply layer
14A spacer layer
14B barrier layer
15 two-dimensional electron gas
21 source electrode
22 drain electrode
23 gate electrode
SA, SB, SC switching element

1. A method for producing a nitride semiconductor stacked body, the method comprising:
a first nitride semiconductor layer forming step of forming a first nitride semiconductor layer above a substrate within a reaction furnace;
a second nitride semiconductor layer forming step of forming a second nitride semiconductor layer above the first nitride semiconductor layer; and
a third nitride semiconductor layer forming step of forming a third nitride semiconductor layer on an upper surface of the second nitride semiconductor layer, the third nitride semiconductor layer having a band gap larger than a band gap of the second nitride semiconductor layer,
wherein no interval is provided between the second nitride semiconductor layer forming step and the third nitride semiconductor layer forming step, and the third nitride semiconductor layer forming step is performed continuously after the second nitride semiconductor layer forming step,
wherein the second nitride semiconductor layer forming step includes
a fourth nitride semiconductor layer forming step of forming a fourth nitride semiconductor layer and
a fifth nitride semiconductor layer foil ling step of forming a fifth nitride semiconductor layer above the fourth nitride semiconductor layer,
wherein a temperature of the substrate in the fifth nitride semiconductor layer forming step is higher than the temperature of the substrate in the fourth nitride semiconductor layer forming step, and
wherein a pressure inside the furnace in the fifth nitride semiconductor layer forming step is lower than the pressure inside the furnace in the fourth nitride semiconductor layer forming step.

2. (canceled)

3. The method for producing a nitride semiconductor stacked body according to claim 1,
wherein the second nitride semiconductor layer forming step further includes a sixth nitride semiconductor layer forming step of forming a sixth nitride semiconductor layer between the fourth nitride semiconductor layer and the fifth nitride semiconductor layer,
wherein the temperature of the substrate in the sixth nitride semiconductor layer forming step gradually changes from the temperature of the substrate in the fourth nitride semiconductor layer forming step to the temperature of the substrate in the fifth nitride semiconductor layer forming step, and
wherein the pressure inside the furnace in the sixth nitride semiconductor layer forming step gradually changes from the pressure inside the furnace in the fourth nitride semiconductor layer forming step to the pressure inside the furnace in the fifth nitride semiconductor layer forming step.

4. The method for producing a nitride semiconductor stacked body according to claim 1,
wherein the second nitride semiconductor layer is made of GaN, and
the third nitride semiconductor layer is made of AlₓGa₁₋ₓN (0<x<1).

5.-9. (canceled)
